(19) United States
(12) Patent Application Publication
(10) Pub. No.: US 2023/0253764 A1
(43) Pub. Date: Aug. 10, 2023

(54) SURFACE EMITTING LASER DEVICE AND ELECTRONIC APPARATUS

(71) Applicant: Sony Semiconductor Solutions Corporation, Kanagawa (JP)

(72) Inventor: Kato Kikufumi, Kanagawa (JP)

(21) Appl. No.: 18/015,612

(22) PCT Filed: Aug. 4, 2021
(86) PCT No.: PCT/JP2021/028990

§ 371 Date: Jan. 11, 2023

(30) Foreign Application Priority Data
Aug. 11, 2020 (JP) 2020-135887

(51) Int. Cl. H01S 5/42; H01S 5/042; H01S 5/00; G01S 7/4865; H01S 5/0683; G01S 7/481; G01C 3/06

(52) U.S. Cl. CPC H01S 5/423; H01S 5/0425; H01S 5/0028; G01S 7/4865; H01S 5/0683; G01S 7/4815; G01C 3/06

(57) ABSTRACT

To enable downsizing and prevent an adverse effect on distance measurement.

A surface emitting laser device includes a surface emitting section having a plurality of light emitting elements arranged on a substrate, and some of the plurality of light emitting elements are used as light receiving elements.

### TECHNICAL FIELD

The present disclosure relates to a surface emitting laser device and an electronic apparatus.

### BACKGROUND ART

In recent years, various sensors are mounted on portable information terminals such as smartphones, and these sensors are used to perform imaging with high sensitivity and high quality. In cameras built in the portable information terminals, autofocus (AF) is generally performed using contrast of an image. However, in a case where contrast of a subject is low such as in a dark place, it takes time to perform AF, and AF accuracy is significantly reduced.

Therefore, portable information terminals that perform AF using a distance measurement sensor of a time of flight (ToF) method are increasing (see Patent Documents 1 and 2). In the ToF method, a distance to a subject is measured by a time difference between a timing of irradiating the subject with laser light and a timing of receiving reflected light from the subject, and the distance to the subject can be accurately measured even in a case where contrast is low such as in a dark place.

### CITATION LIST

### Patent Document

Patent Document 1: Japanese Patent Application Laid-Open No. 2019-16615
Patent Document 2: Japanese Patent Application Laid-Open No. 2019-132640

### SUMMARY OF THE INVENTION

### Problems to be Solved by the Invention

However, in a case where the distance is measured by the ToF method, it is necessary to provide a light receiving element that detects a timing at which a light emitting element emits light and a light receiving element that receives reflected light, which is the light emitted by the light emitting element and reflected from the subject, and downsizing is difficult, so that there is a problem that mounting on a small portable information terminal such as a smartphone is not possible.

Patent Document 2 discloses a technology in which a light receiving element that detects a timing at which a light emitting element emits light and a light receiving element that receives reflected light, which is the light emitted by the light emitting element and reflected by a subject, are integrated into one. However, if once receiving light, the light receiving element using an avalanche photodiode needs to perform a quenching operation once until the light can be received thereafter. Thus, if the two light receiving elements described above are integrated into one, there is a possibility that reception of the reflected light from a short distance fails so that a distance measurement range is narrowed.

Therefore, the present disclosure provides a surface emitting laser device and an electronic apparatus that can be downsized and do not adversely affect distance measurement.

### Solutions to Problems

In order to solve the problem described above, the present disclosure provides a surface emitting laser device including a surface emitting section having a plurality of light emitting elements arranged on a substrate, some of the plurality of light emitting elements being used as light receiving elements.

An optical system that outputs the light emitted from the surface emitting section may be provided,

in which the plurality of light emitting elements may include:

a first element that emits light; and

a second element that receives light which is the light emitted from the first element and reflected by the optical system.

A forward bias voltage may be supplied to the first element, and a reverse bias voltage may be supplied to the second element.

A cathode of the first element and a cathode of the second element may be connected in common, a power supply voltage may be supplied to an anode of the first element, and a signal corresponding to a received light amount may be output from an anode of the second element.

A light source driving section, which is connected to the cathode of the first element and the cathode of the second element and switches whether or not to cause a current corresponding to an emitted light intensity to flow to the first element, may be provided.

The light source driving section may variably control a current flowing through the first element when the first element is caused to emit light on the basis of an amount-of-light signal indicating a light intensity of light received by the second element.

A voltage conversion circuit, which is connected between the anode of the second element and a reference voltage node and generates a voltage signal corresponding to an intensity of light received by the second element, may be provided.

The plurality of light emitting elements may be arranged in a first direction and a second direction intersecting each other on the substrate, and four light emitting elements at four corners out of the plurality of light emitting elements may be used as the light receiving elements.

The plurality of light emitting elements may be classified into a plurality of light emitting element groups each including two or more of the light emitting elements, each of the plurality of light emitting element groups may be sequentially caused to emit light in a time-shifted manner, and the light emitting elements included in the light emitting element group that does not emit light may be used as the light receiving elements.

The plurality of light emitting element groups may be formed by arranging the light emitting element groups each including two or more light emitting elements arranged in a first direction to form a plurality of columns in a second direction intersecting the first direction, each of the light emitting element groups in the plurality of columns may be sequentially caused to emit light column by column in a time-shifted manner, and the light emitting elements included in the light emitting element group of a column that does not emit light may be used as the light receiving elements.

Some light emitting elements out of the plurality of light emitting elements may be test light emitting elements, the test light emitting elements may be arranged at a different place on the substrate from light emitting elements other than the some light emitting elements, and the test light emitting elements may be used as the light receiving elements.

In one aspect of the present disclosure, a surface emitting section having a plurality of light emitting elements arranged on a substrate; an optical system configured to output light emitted from the surface emitting section; and a control section that controls light intensities of the plurality of light emitting elements may be provided, the plurality of light emitting elements may include a first element that emits light, and a second element that receives light, which is the light emitted from the first element and reflected by the optical system, and the control section may control a light intensity of the first element on the basis of an intensity of the light received by the second element.

An amount-of-light signal generation circuit, which generates an amount-of-light signal indicating the intensity of the light received by the second element, may be provided, and the control section may control light intensity of the first element on the basis of the amount-of-light signal.

A current source, which variably controls a current flowing through the first element when the first element is caused to emit light, may be provided, and the control section may adjust the current of the current source on the basis of the amount-of-light signal.

A light source driving section, which controls whether or not to cause the first element to emit light, may be provided, and the control section may stop the light emission of the first element in a case where the amount-of-light signal exceeds a predetermined reference amount.

A reference signal generation circuit, which generates a reference signal indicating a timing at which light is received by the second element, may be provided.

A light receiving element, which receives reflected light which is the light emitted from the first element and is reflected by an object, and a time measuring section, which detects a time difference between a time at which the light receiving element receives the reflected light and a time at which the first element emits light on the basis of a light receiving signal output from the light receiving element and the reference signal, may be provided.

A determination section, which determines whether or not the second element has received light until a lapse of a predetermined time after the first element receives light, and a warning section, which performs predetermined warning processing when the determination section determines that the second element has not received light until the lapse of the predetermined time, may be provided.

A first semiconductor device including the surface emitting section and a second semiconductor device including the control section may be provided, and the optical system may be arranged on a light output surface side of the first semiconductor device.

### BRIEF DESCRIPTION OF DRAWINGS

FIG. 1 is a cross-sectional view of a distance measurement module including a surface emitting laser device according to a first embodiment.

FIG. 2 is a schematic cross-sectional view depicting a schematic configuration of a light emitting section.

FIG. 3 is a cross-sectional view depicting structures of an LDD substrate and an LD chip of the light emitting section in FIG. 1 in more detail.

FIG. 4 is a plan view depicting an arrangement of a plurality of light emitting elements in the light emitting section.

FIG. 5 is a plan view of a surface emitting laser device having a test light emitting element.

FIG. 6 is a diagram depicting an example of a connection form of the light emitting section in the distance measurement module.

FIG. 7 is a block diagram depicting an example of an internal configuration of an electronic apparatus according to the present embodiment.

FIG. 8 is a diagram for describing a time of flight measured by a time measurement section.

FIG. 9 is a circuit diagram depicting a connection form of each light emitting element of a surface emitting laser device according to a second embodiment.

FIG. 10 is a diagram depicting an arrangement example of a first light emitting element group and a second light emitting element group.

FIG. 11 is a circuit diagram in which an integration circuit and a waveform shaping circuit are added as a modified example of FIG. 9.

FIG. 12 is an equivalent circuit diagram of FIG. 11.

FIG. 13 is a diagram for schematically describing a distance measurement module according to a third embodiment.

FIG. 14 is a block diagram of the electronic apparatus including a warning section.

FIG. 15 is a block diagram depicting a schematic configuration of an electronic apparatus according to a fourth embodiment.

FIG. 16 is a diagram depicting an example of the electronic apparatus according to the present disclosure.

FIG. 17 is a diagram depicting an example of the electronic apparatus according to the present disclosure.

FIG. 18 is a block diagram depicting an example of a schematic configuration of a vehicle control system.

FIG. 19 is a diagram of assistance in describing an example of installation positions of an outside-vehicle information detecting section and an imaging section.

### MODE FOR CARRYING OUT THE INVENTION

Hereinafter, embodiments of a surface emitting laser device and an electronic apparatus will be described with reference to the drawings. Hereinafter, description will be given focusing on main constituent portions of the surface emitting laser device and the electronic apparatus, but the surface emitting laser device and the electronic apparatus may have constituent portions or functions that are not illustrated or described. The following description does not exclude the constituent portions or functions that are not illustrated or described.

### First Embodiment

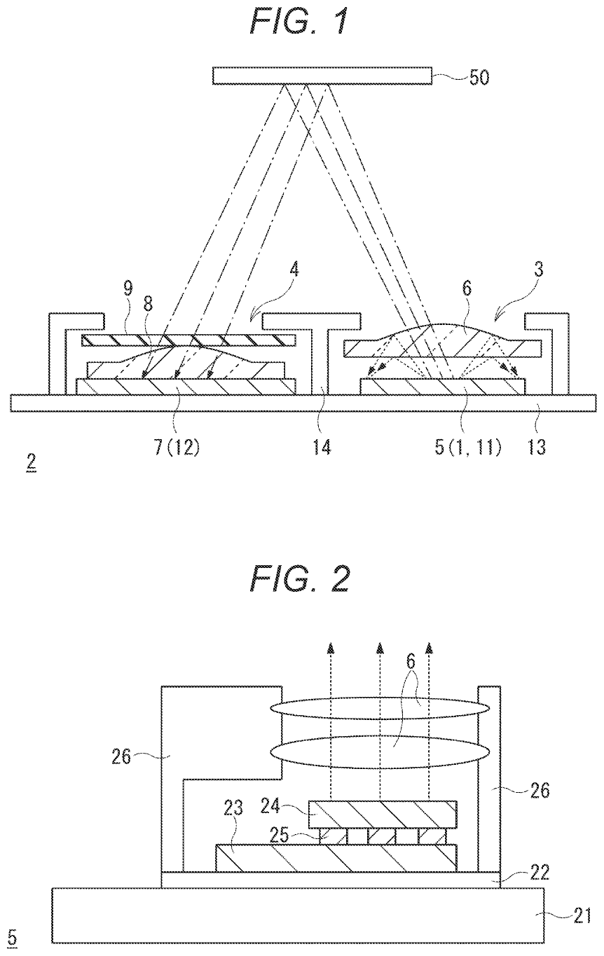

FIG. 1 is a cross-sectional view of a distance measurement module 2 including a surface emitting laser device 1 according to a first embodiment. The distance measurement module 2 in FIG. 1 includes the distance measurement module 2 that measures a distance to an object (distance measurement target) 50 by a ToF method. The distance measurement module 2 includes a light emitting device 3 and a light receiving device 4. The distance measurement module 2 can be incorporated in an electronic apparatus such as a smartphone as described later.

The light emitting device 3 includes a light emitting section 5 and an output optical system 6. The light emitting section 5 includes the surface emitting laser device 1.

As described later, the surface emitting laser device 1 is a vertical cavity surface emitting laser (VCSEL) in which a plurality of light emitting elements is two-dimensionally arranged on a semiconductor substrate, and the plurality of light emitting elements simultaneously outputs laser light in a predetermined wavelength band. Therefore, the laser light emitted from the plurality of light emitting elements becomes light spreading in a planar shape.

The output optical system 6 is arranged to face a light output surface of the surface emitting laser device 1. The output optical system 6 shapes the light emitted from the surface emitting laser device 1 into a predetermined beam diameter and radiates the light along an output optical axis. A light input surface of the output optical system 6 and the light output surface on the opposite side thereof do not transmit but reflect about 4 to 7% of light incident on the respective surfaces. Therefore, about 8 to 14% of the incident light is reflected by the entire output optical system 6. A reflection ratio of the incident light can be reduced to about 1% by depositing an anti-reflection coating film on each of the surfaces. That is, the reflection ratio of the output optical system 6 can be controlled within a range of about 1 to 14% by adjusting the anti-reflection coating film provided in the output optical system 6. As described later, some of the plurality of light emitting elements in the surface emitting laser device 1 are used as light receiving elements to receive the light reflected by the output optical system 6 in the present embodiment.

The light receiving device 4 includes a light receiving section 7, an input optical system 8, and a band-pass filter 9. The light receiving section 7 includes a single photon avalanche diode (SPAD) array in which a plurality of SPADs is two-dimensionally arranged. The SPAD operates in a Geiger mode in which a large current flows by performing avalanche multiplication on one incident photon. Therefore, even a small light amount of incident light can be detected. On the other hand, there is a limitation that it is difficult to detect new incident light until completion of a quenching operation of discharging electrons generated and accumulated by the avalanche multiplication to return to an initial voltage. Various measures for speeding up the quenching operation may be taken, but the description thereof is omitted in the present specification.

The input optical system 8 is arranged to face a light receiving surface of the light receiving section 7. The band-pass filter 9 is provided to remove noise light such as ambient light.

The surface emitting laser device 1 constituting the light emitting section 5 and the SPAD array constituting the light receiving section 7 can include separate semiconductor chips, respectively. FIG. 1 illustrates an example in which a semiconductor chip 11 including the built-in surface emitting laser device 1 and a semiconductor chip 12 including the built-in SPAD array are mounted on a common support substrate 13. A light shielding member 14 is arranged between the semiconductor chip 12 including the built-in SPAD array and the semiconductor chip 11 including the built-in surface emitting laser device 1 such that the light emitted from the surface emitting laser device 1 is not reflected by the output optical system 6 or a housing of the electronic apparatus and is not incident on the SPAD array before being reflected by the object.

On the semiconductor chip 12 including the built-in SPAD array, a chip on which a circuit of a control system of the distance measurement module 2 has been formed is stacked. This circuit measures the distance to the object on the basis of a time difference between a timing at which a light emitting element emits light and a timing at which a light receiving element receives light.

In the present embodiment, some of the plurality of light emitting elements in the surface emitting laser device 1 constituting the light emitting section 5 are used as the light receiving elements. The surface emitting laser device 1 is known to have reversibility. When a forward bias voltage is applied between an anode and a cathode of a light emitting element, the light emitting element can be caused to emit light. On the other hand, when a bias voltage, a zero voltage, or a reverse bias voltage is applied between an anode and a cathode of a light emitting element, the light emitting element can be caused to receive light. In the present embodiment, some of the plurality of light emitting elements are used as the light receiving elements by utilizing such reversibility of the surface emitting laser device 1. Therefore, it is unnecessary to provide a light receiving element other than the SPAD in the distance measurement module 2, and the distance measurement module 2 can be downsized. In the present specification, among the plurality of light emitting elements in the surface emitting laser device 1, the light emitting element used as the light receiving element is sometimes referred to as a first light receiving section. Furthermore, the light receiving section 7 including the SPAD array that receives the reflected light from the object is sometimes referred to as a second light receiving section.

FIG. 2 is a schematic cross-sectional view depicting a schematic configuration of the light emitting section 5. As depicted in FIG. 2, in the light emitting section 5, a laser diode driver (LDD) substrate (first substrate) 23 is arranged on a support substrate 21 via a heat dissipation substrate 22, and a laser diode (LD) chip (second substrate) 24 is arranged on the LDD substrate 23. The LDD substrate 23 and the LD chip 24 are bonded by a bonding member 25 such as a solder bump. The LDD substrate 23 outputs a drive signal for driving a light emitting element to the LD chip 24 via the bonding member 25. The LD chip 24 includes the light emitting element. The light emitting element emits laser light in a predetermined wavelength band in response to the drive signal from the LDD substrate 23. The laser light emitted from the LD chip 24 is radiated to the outside via the output optical system 6. The output optical system 6 is held by the lens holding section 26. The output optical system 6 includes one or more lenses.

A wavelength of the laser light emitted from the LD chip 24 is any wavelength band from a visible light band to an infrared light band. It is desirable to select an appropriate wavelength band according to the application of the distance measurement module 2.

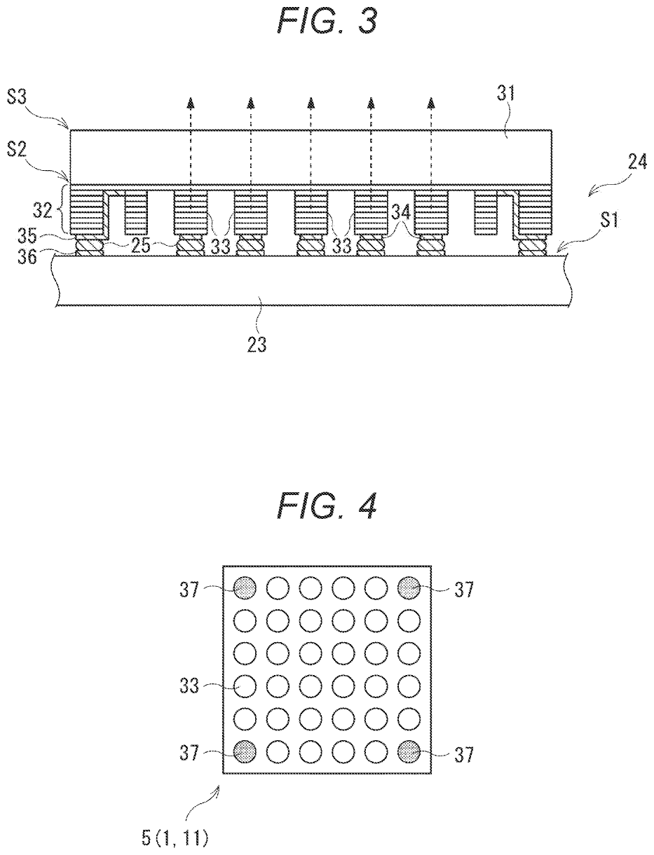

FIG. 3 is a cross-sectional view depicting structures of the LDD substrate 23 and the LD chip 24 of the light emitting section 5 in FIG. 1 in more detail. The LD chip 24 includes a substrate 31, a laminated film 32, a plurality of light emitting elements 33 formed using the laminated film 32, a plurality of anode electrodes 34, and a cathode electrode 35.

The substrate 31 of the LD chip 24 is a substrate including a compound semiconductor such as gallium arsenide (GaAs). A surface of the substrate 31 facing one principal surface S1 of the LDD substrate 23 is a front surface S2, and laser light is emitted from a back surface S3 side of the substrate. As for an electrical polarity of the substrate 31, the N-type substrate 31 is used because a P-type substrate has many crystal defects and has not been practically used. Therefore, the common cathode polarity is used in which the plurality of light emitting elements has the common cathode.

The laminated film 32 includes a first multilayer film reflector, a first spacer layer, an active layer, a second spacer layer, a second multilayer film reflector, and the like, causes laser light generated in the active layer to resonate between the first multilayer film reflector and the second multilayer film reflector to improve the light intensity, and outputs the laser light from the back surface S3 side of the substrate. In this manner, the LD chip 24 in FIG. 3 is a back-illuminated type. The light emitting element 33 having the layer configuration as depicted in FIG. 3 is also referred to as a VCSEL structure.

The plurality of light emitting elements 33 is formed by processing the laminated film 32 into a mesa shape. The anode electrode (second pad) 34 is arranged on an upper surface of each of the light emitting elements 33 when viewed from the substrate 31 side. Similarly, when viewed from the substrate 31 side, the cathode electrode 35 is arranged on an upper surface and a side surface of the laminated film 32 arranged on an end side of the LD chip 24. The cathode electrode 35 is also arranged on a lowermost layer side of the laminated film 32 of the plurality of light emitting elements 33 when viewed from the substrate 31 side.

The LDD substrate 23 includes a plurality of pads 36 configured to supply drive signals to the plurality of light emitting elements 33 of the LD chip 24. The bonding member 25 is arranged on the pad 36, and the pad 36 of the LDD substrate 23 and the pad 34 of the corresponding anode electrode 34 of the LD chip 24 are bonded with the bonding member 25 interposed therebetween.

The LDD substrate 23 may include a drive circuit that generates a drive signal. In this case, the LDD substrate 23 is actively driven. Alternatively, the LDD substrate 23 may include a switching circuit that switches a drive signal generated by an external drive circuit. In this case, the LDD substrate 23 is passively driven.

The distance measurement module 2 receives light reflected by the output optical system 6 of light emitted from the light emitting section 5 in order to detect a timing at which the light is emitted from the light emitting section 5. In order to receive such light, some light emitting elements 33 among the plurality of light emitting elements 33 in the light emitting section 5 are used as the light receiving elements 37 in the present embodiment.

FIG. 4 is a plan view depicting an arrangement of the plurality of light emitting elements 33 in the light emitting section 5. As illustrated, the plurality of light emitting elements 33 is arranged in a first direction and a second direction intersecting each other in the light emitting section 5. That is, the plurality of light emitting elements 33 is arranged in a two-dimensional direction. Since the light emitting section 5 according to the present embodiment performs surface light emission, it is desirable to detect received light intensities at positions uniformly dispersed in a plane rather than to detect received light intensities at specific positions in the plane in order to detect an average received light intensity of planar light. From such a viewpoint, for example, four light emitting elements 33 at four corners are used as the light receiving element 37.

Note that which light emitting element 33 is used as the light receiving element 37 among the plurality of light emitting elements 33 in the light emitting section 5 is arbitrary. For example, the light emitting element 33 at the center may also be used as the light receiving element 37 in addition to the light emitting elements 33 at the four corners as depicted in FIG. 4. Alternatively, among the plurality of light emitting elements 33 arranged in a rectangular shape, the light emitting element 33 at the center of each edge may be used as the light receiving element 37. Alternatively, a plurality of light emitting elements 33 arranged diagonally may be used as the light receiving elements 37.

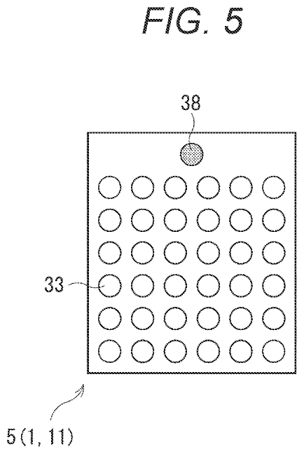

There is a case where the surface emitting laser device 1 is provided with a test light emitting element. For example, as depicted in FIG. 5, the test light emitting element 38 is often provided at a place away from the original light emitting element 33. The test light emitting element 38 is provided to test an emitted light intensity or the like of the surface emitting laser device 1. Such a test light emitting element 38 may be used as the light receiving element 37. In this case, the original light emitting element 33 can be used to emit light without any change, and thus, the amount of change in wiring can be reduced, and design can be easily changed.

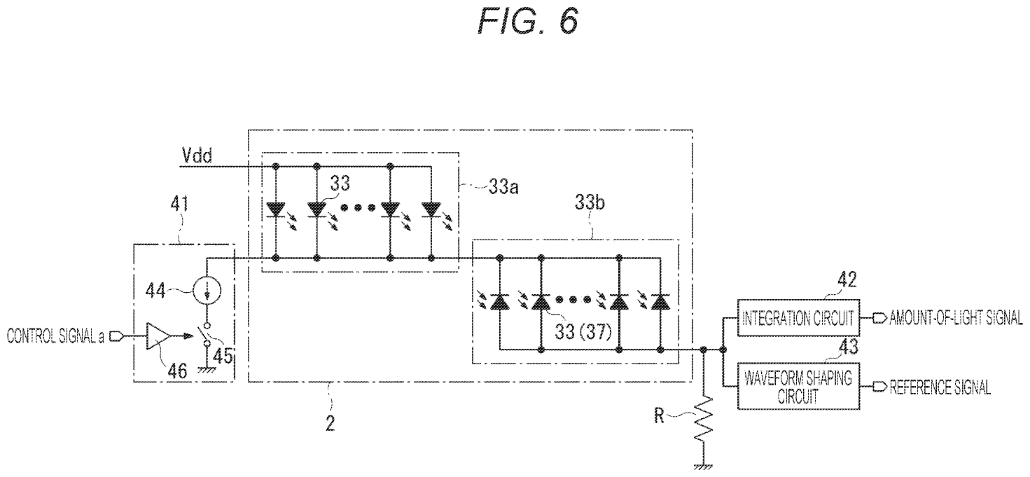

FIG. 6 is a diagram depicting an example of a connection form of the light emitting section 5 in the distance measurement module 2. FIG. 6 also illustrates a light source driving section 41, an integration circuit (amount-of-light signal generation circuit) 42, and a waveform shaping circuit (reference signal generation circuit) 43 in the electronic apparatus 40 in addition to the light emitting section 5 in the distance measurement module 2.

As depicted in FIG. 6, the light emitting section 5 includes a first element 33a used to emit light and a second element 33b used to receive light among the plurality of light emitting elements 33. FIG. 6 illustrates an example in which the first element 33a includes two or more light emitting elements 33 and the second element 33b also includes two or more light emitting elements 33, but the number of light emitting elements 33 included in the first element 33a and the number of light emitting elements 33 included in the second element 33b are arbitrary.

The respective light emitting elements 33 constituting the first element 33a are connected in parallel, each of the light emitting elements 33 has an anode connected to a power supply voltage node and a cathode connected to an output node of the light source driving section 41.

The light source driving section 41 is a driver that controls a current flowing through each of the light emitting elements 33 constituting the first element 33a. The light source driving section 41 is arranged, for example, in the vicinity of the light emitting section 5 in FIG. 1. The light source driving section 41 includes a current source 44, a selector 45, and a buffer 46. The current source 44 controls a current flowing through the first element 33a by a control section as described later. The selector 45 switches whether or not the current source 44 allows the current to flow according to logic of a control signal a input via the buffer 46. For example, when the control signal a is at a high potential, the selector 45 is turned on, and the current source 44 causes the current to flow. Each of the light emitting elements constituting the first element 33a emits light with a light intensity corresponding to the current flowing through the current source 44. In this manner, the emitted light intensity of each of the light emitting elements 33 constituting the first element 33a depends on the current flowing through the current source 44. The current flowing through the current source 44 is controlled by the control section as described later.

The respective light emitting elements 33 constituting the second element 33b are also connected in parallel. A cathode of each of the light emitting elements 33 constituting the second element 33b is connected to the output node of the light source driving section 41 together with the cathode of each of the light emitting elements 33 constituting the first element 33a. For example, assuming that a power supply voltage is 5 V and a voltage between the anode and the cathode when each of the light emitting elements 33 constituting the first element 33a emits light is 2 V, a voltage of the cathode of the first element 33a (cathode of the second element 33b) is about 3 V. Thus, each of the light emitting elements 33 constituting the second element 33b is set in a reverse bias state. In this state, a PN-junction capacitance of each of the light emitting elements 33 constituting the second element 33b becomes small, and a higher-speed operation becomes possible.

Part of the light emitted from each of the light emitting elements 33 constituting the first element 33a is reflected by the output optical system 6 and received by each of the light emitting elements 33 constituting the second element 33b as indicated by broken lines in FIG. 1. Since the output optical system 6 is arranged in the vicinity of the light emitting section 5, a timing at which each of the light emitting elements 33 constituting the second element 33b receives the light is substantially the same as a timing at which each of the light emitting elements 33 constituting the first element 33a emits the light. Furthermore, a light intensity (received light amount) of the light received by each of the light emitting elements 33 constituting the second element 33b changes according to the light intensity of emission of each of the light emitting elements 33 constituting the first element 33a.

A resistor R is connected between the anode of each of the light emitting elements 33 constituting the second element 33b and a ground node. The resistor R functions as a voltage conversion circuit that converts a current flowing through the anode of each of the light emitting elements 33 constituting the second element 33b into a voltage. A voltage across the resistor R becomes a voltage level corresponding to the received light amount in each of the light emitting elements 33 constituting the second element 33b, and the voltage level increases as the received light amount increases.

In this manner, the surface emitting laser device 1 outputs a voltage corresponding to the received light amount in each of the light emitting elements 33 constituting the second element 33b. This voltage is input to the integration circuit 42 and the waveform shaping circuit 43. The integration circuit 42 integrates the voltage corresponding to the received light amount of each of the light emitting elements 33 constituting the second element 33b with respect to time to generate an amount-of-light signal. The waveform shaping circuit 43 shapes a waveform of a light receiving signal in each of the light emitting elements 33 constituting the second element 33b to generate a pulse signal. The pulse signal is a reference signal indicating the timing at which each of the light emitting elements 33 constituting the first element 33a emits the light.

In this manner, some light emitting elements 33 among the plurality of light emitting elements 33 in the light emitting section 5 are used as the light receiving elements 37, and thus, a light intensity and a light emission timing of light emitted by the light emitting section 5 can be accurately detected without separately providing the light receiving elements 37. Furthermore, it is unnecessary to use the light receiving section 7 provided to receive light from an object to detect the intensity and the light emission timing of the light emitted from the light emitting section 5 according to the present embodiment. Thus, when the light receiving section 7 receives a reflection signal from the output optical system 6, a problem that it is difficult to receive reflected light from the object within a period (dead time) in which light reception is impossible due to the quenching operation of the SPAD does not occur, so that the distance measurement at a short distance can also be performed, and a distance measurement range can be expanded.

Note that, in a case where the number of light emitting elements 33 used as the light receiving elements 37 is small among the plurality of light emitting elements 33 in the light emitting section 5, the light energy that can be received by one light receiving element 37 is not necessarily sufficient, and thus, there is a possibility that it is difficult to accurately detect the amount-of-light signal and the reference signal described above only by one-time measurement. Therefore, it is desirable to perform a plurality of times of light reception in accordance with a plurality of times of light emission of the light emitting section 5 and improve measurement accuracy of the amount-of-light signal and the reference signal by averaging processing.

A proportionality constant between a light signal level emitted from the light emitting section 5 and transmitted through the output optical system 6 and the voltage level reflected by the output optical system 6, received by some of the light emitting elements 33 in the light emitting section 5, and appearing across the resistor R is calibrated in advance in consideration of individual differences, temperature coefficients, and the like, whereby a quantitative numerical value can be obtained. Furthermore, a ratio of the light incident on and reflected by the output optical system 6 can be changed by adjusting the amount of coating of the anti-reflection coating film formed on the surface of the output optical system 6.

As described later, auto power control (APC) for automatically adjusting the light intensity of the light emitted from the light emitting section 5 may be performed, or the light intensity of the light emitted from the light emitting section 5 may be adjusted such that the amount-of-light signal matches the reference signal prepared in advance by monitoring the amount-of-light signal output from the integration circuit 42. Therefore, the light intensity of the light emitted from the light emitting section 5 can be stabilized, and the distance can be measured with higher accuracy.

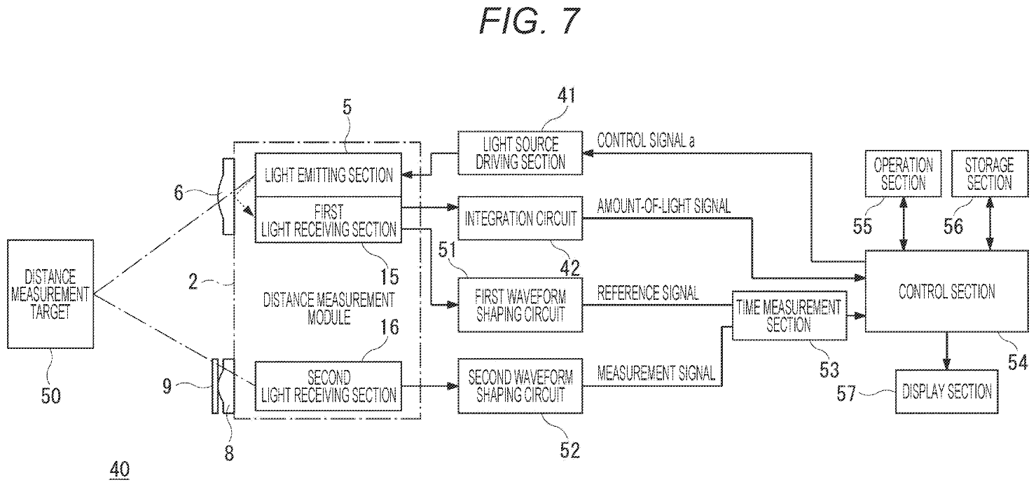

FIG. 7 is a block diagram depicting an example of an internal configuration of the electronic apparatus 40 according to the present embodiment. As depicted in FIG. 7, the electronic apparatus 40 includes the distance measurement module 2, the light source driving section 41, the integration circuit 42, a first waveform shaping circuit 51, a second waveform shaping circuit 52, a time measurement section 53, a control section 54, an operation section 55, a storage section 56, and a display section 57.

The distance measurement module 2 includes the light emitting section 5, a first light receiving section 15, and a second light receiving section 16. Note that the light emitting section 5 in FIG. 7 indicates the light emitting element 33 that emits light among the plurality of light emitting elements 33 constituting the light emitting section 5. In the distance measurement module 2, the object (distance measurement target) 50 is irradiated with the light emitted from the light emitting section 5 and transmitted through the output optical system 6, and the reflected light from the object (measurement target) 50 is received by the second light receiving section 16.

As depicted in FIG. 6, the first light receiving section 15 indicates the light emitting element 33 used as the light receiving element 37 among the plurality of light emitting elements 33 in the light emitting section 5. The second light receiving section 16 is the light receiving section 7 including the SPAD array depicted in FIG. 1. The output optical system 6 is provided in the vicinity of the light emitting section 5 and the first light receiving section 15. The input optical system 8 and the band-pass filter 9 are provided in the vicinity of the second light receiving section 16.

As depicted in FIG. 6, a light receiving signal of the first light receiving section 15 is converted into a voltage by the resistor R. This voltage is input to the integration circuit 42 and the first waveform shaping circuit 51. A light receiving signal of the second light receiving section 16 is input to the second waveform shaping circuit 52. In practice, the light receiving signal of the second light receiving section 16 is also converted into a voltage by a resistor R (not illustrated) or the like and input to the second waveform shaping circuit 52.

The light source driving section 41 switches whether or not to drive each of the light emitting elements 33 in the light emitting section 5 in synchronization with a pulse of the control signal a. Furthermore, the light source driving section 41 adjusts the current flowing through each of the light emitting elements 33 in the light emitting section 5 according to an instruction from the control section 54. As depicted in FIG. 6, the output node of the light source driving section 41 is connected to the cathodes of the respective light emitting elements 33 of the light emitting section 5 and the first light receiving section 15.

As depicted in FIG. 6, the integration circuit 42 performs integration processing on the voltage corresponding to the light receiving signal of the first light receiving section 15 to generate an amount-of-light signal. The integration circuit 42 transmits the generated amount-of-light signal to the control section 54.

The first waveform shaping circuit 51 performs integration processing on the voltage corresponding to the light receiving signal of the second light receiving section 16 to generate a reference signal. The second waveform shaping circuit 52 generates a measurement signal on the basis of the voltage corresponding to the light receiving signal of the second light receiving section 16.

The time measurement section 53 measures a time of flight (ToF) which is a time difference between a timing of the measurement signal and a timing of the reference signal.

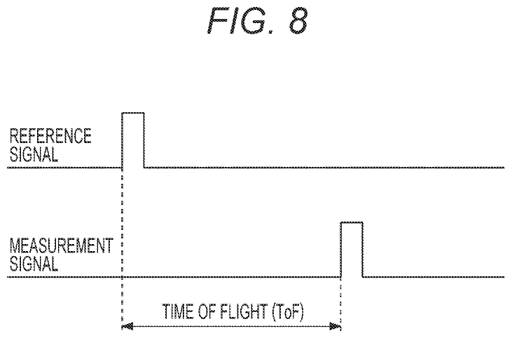

FIG. 8 is a diagram for describing the time of flight measured by the time measurement section 53. For example, the time measurement section 53 measures a time difference between a timing of a rising edge of the pulse-shaped reference signal and a timing of a rising edge of the pulse-shaped measurement signal as the time of flight (ToF). The time measurement section 53 transmits the measured time of flight to the control section 54.

The control section 54 adjusts the amount of current flowing through the current source 44 in the light source driving section 41 on the basis of the amount-of-light signal. Furthermore, the control section 54 transmits the control signal a indicating the timing at which the light emitting section 5 emits light to the light source driving section 41.

The control section 54 includes, for example, a processor such as a CPU. The operation section 55 and the storage section 56 are connected to the control section 54. The operation section 55 includes, for example, various operation devices configured to operate the electronic apparatus 40 such as a switch, a button, a keyboard, and a touch panel. The control section 54 controls each section of the electronic apparatus 40 on the basis of, for example, an operation signal from the operation section 55 or executes a program stored in the storage section 56 to perform predetermined processing. For example, the control section 54 performs processing based on a measurement result of the distance measurement module 2.

Next, a processing operation of the electronic apparatus 40 according to the first embodiment will be described. When the control section 54 transmits the control signal a to the light source driving section 41, the light source driving section 41 causes the current to flow through the cathode of each of the light emitting elements 33 in the light emitting section 5 in synchronization with the pulse included in the control signal a. Therefore, each of the light emitting elements 33 starts to emit light. Most of the emitted light is transmitted through the output optical system 6, but part of the emitted light is reflected by the input surface or the output surface of the output optical system 6 and received by the first light receiving section 15. The first light receiving section 15 is a part of the light emitting elements 33 among the plurality of light emitting elements 33 in the surface emitting laser device 1. The light receiving signal output from the first light receiving section 15 is converted into the voltage and input to the integration circuit 42 and the first waveform shaping circuit 51 to generate the amount-of-light signal and the reference signal.

Most of the light emitted from the light emitting section 5 is transmitted through the output optical system 6 and is reflected by the object, and the reflected light is received by the second light receiving section 16. The second light receiving section 16 includes the SPAD. The light receiving signal of the second light receiving section 16 is input to the second waveform shaping circuit 52 to generate the measurement signal.

The time measurement section 53 irradiates the object with light on the basis of the reference signal generated by the first waveform shaping circuit 51 and the measurement signal generated by the second waveform shaping circuit 52, and measures the time of flight of the light until the reflected light is received.

The control section 54 measures the distance to the object on the basis of the time of flight measured by the time measurement section 53. Furthermore, the control section 54 controls the current flowing through the light emitting element 33 in the light emitting section 5 on the basis of the amount-of-light signal generated by the integration circuit 42. Therefore, the light intensity of the light emitted from the light emitting section 5 can be adjusted.

In this manner, some light emitting elements 33 among the plurality of light emitting elements 33 in the surface emitting laser device 1 are used as the light receiving elements 37 in the first embodiment. More specifically, some light emitting elements 33 among the plurality of light emitting elements 33 in the light emitting section 5 are used as the first light receiving section 15 that receives light emitted from the light emitting section 5 and reflected by the input surface or the output surface of the output optical system 6. Therefore, it is unnecessary to provide a separate light receiving element 37 as the first light receiving section 15, and member cost can be reduced, and the electronic apparatus 40 can be downsized.

In the present embodiment, in a case where some light emitting elements 33 among the plurality of light emitting elements 33 in the surface emitting laser device 1 are used as the light receiving elements 37, it is only required to connect the anodes of the light emitting elements 33 used as the light receiving elements 37 to the integration circuit 42 and the waveform shaping circuit 43 instead of the power supply voltage node without changing a connection destination of the cathode of each of the light emitting elements 33, and thus, the light emitting element 33 can be changed to the light receiving element 37 only by partially changing the wiring, and the design can be easily changed.

Furthermore, the amount-of-light signal is generated on the basis of the light receiving signal in the first light receiving section 15, and the control section 54 controls the light intensity of the light emitted from the light emitting section 5 on the basis of the amount-of-light signal, so that the light intensity of the light emitted from the light emitting section 5 can be optimized.

### Second Embodiment

In a second embodiment, the plurality of light emitting elements 33 in the surface emitting laser device 1 is classified into a plurality of light emitting element groups, and each of the plurality of light emitting element groups sequentially emits light in a time-shifted manner.

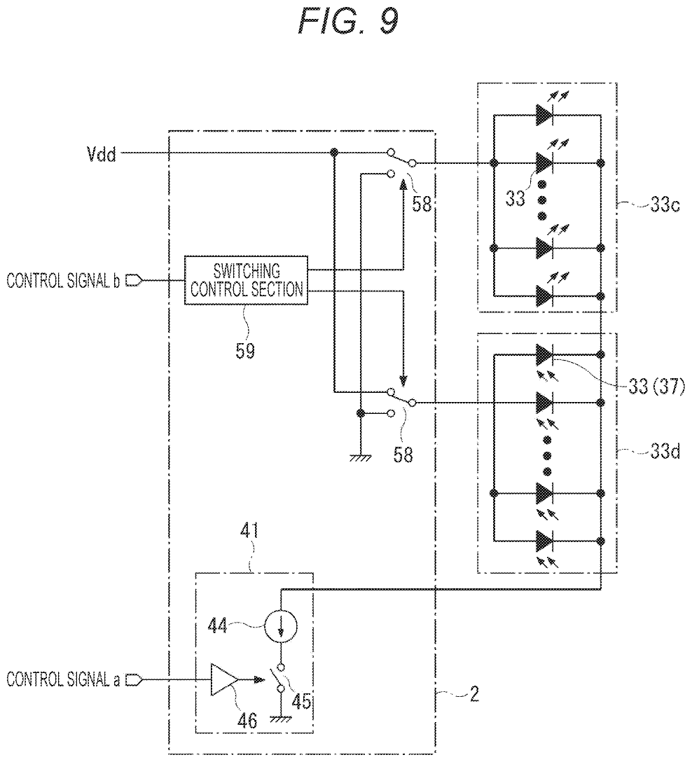

FIG. 9 is a circuit diagram depicting a connection form of the light emitting elements 33 of the surface emitting laser device 1 according to the second embodiment. In FIG. 9, the plurality of light emitting elements 33 in the surface emitting laser device 1 is classified into a first light emitting element group 33c and a second light emitting element group 33d, and a switching operation is alternately performed to use one of the first light emitting element group 33c and the second light emitting element group 33d as the light emitting element 33 and use the other as the light receiving element 37.

The surface emitting laser device 1 of FIG. 9 includes the plurality of light emitting elements 33, a selector 58, and a switching control section 59. The selector 58 performs switching to connect any one of an anode of each of the light emitting elements 33 in the first light emitting element group 33c and an anode of each of the light emitting elements 33 in the second light emitting element group 33d to a power supply voltage node and connect the other to a ground node. The switching control section 59 controls the switching of the selector 58 on the basis of a control signal b from the control section 54.

The switching control section 59 connects the anodes of the light emitting elements 33 in the second light emitting element group 33d to the ground node when connecting the anodes of the light emitting elements 33 in the first light emitting element group 33c to the power supply voltage node, and connects the anodes of the light emitting elements 33 in the first light emitting element group 33c to the ground node when connecting the anodes of the light emitting elements 33 in the second light emitting element group 33d to the power supply voltage node. The switching control section 59 alternately performs such connection switching.

In a case where the surface emitting laser device 1 of FIG. 9 is incorporated in the distance measurement module 2, the number of the light emitting elements 33 that simultaneously emit light can be reduced as compared with a case where a distance is measured by emitting light from all the light emitting elements 33 in the surface emitting laser device 1, and thus, power consumption of the light emitting section 5 can be reduced without affecting a distance measurement range. Furthermore, the surface emitting laser device 1 according to the second embodiment uses the light emitting element 33 that does not emit light as the light receiving element 37, and thus, it is possible to generate a reference signal and an amount-of-light signal similarly to the first embodiment by using some of the light emitting elements 33 in the surface emitting laser device 1 as the light receiving elements 37. Thus, a separate light receiving element configured to generate the reference signal and the amount-of-light signal is unnecessary, and downsizing is possible.

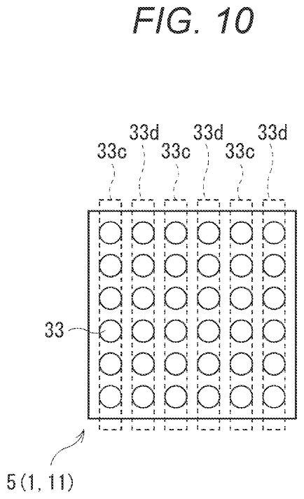

FIG. 10 is a view depicting an arrangement example of the first light emitting element group 33c and the second light emitting element group 33d. FIG. 10 illustrates an example in which the plurality of light emitting elements 33 in the surface emitting laser device 1 is arranged in a rectangular shape, and among the respective columns indicated by broken lines, odd columns are the first light emitting element groups 33c and even columns are the second light emitting element groups 33d. Note that FIG. 10 is an example, and a way of classification into the first light emitting element group 33c and the second light emitting element group 33d is arbitrary. For example, an odd row may be the first light emitting element group 33c, and an even row may be the second light emitting element group 33d. Furthermore, classification into three or more light emitting element groups may be performed, each of the light emitting element groups may be caused to sequentially emit light, and a light emitting element group that is not caused to emit light may be used as the light receiving element 37.

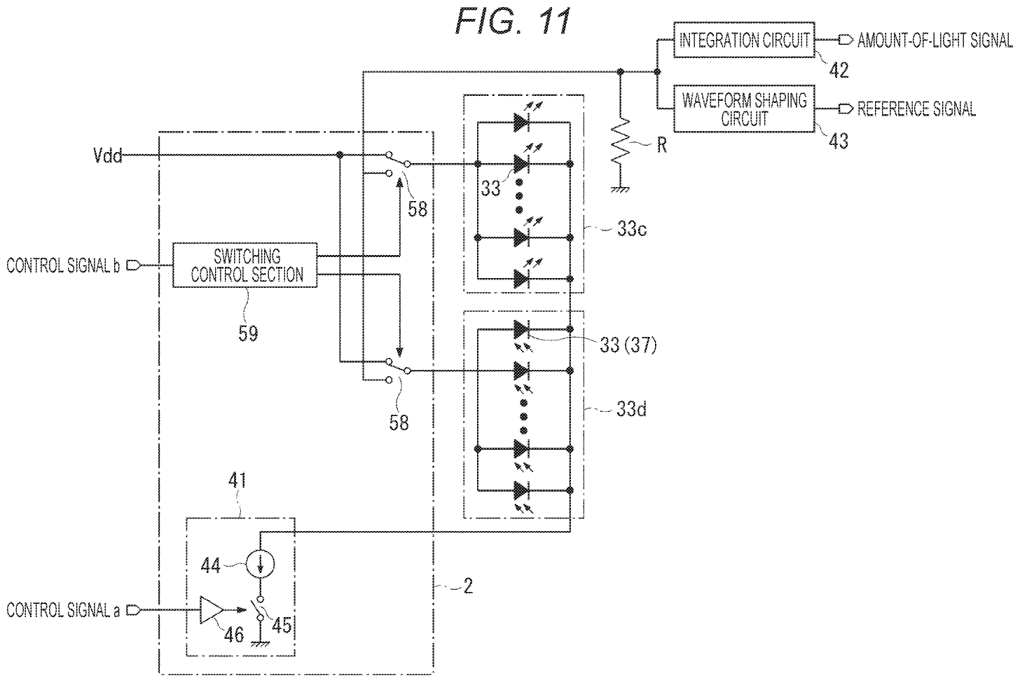

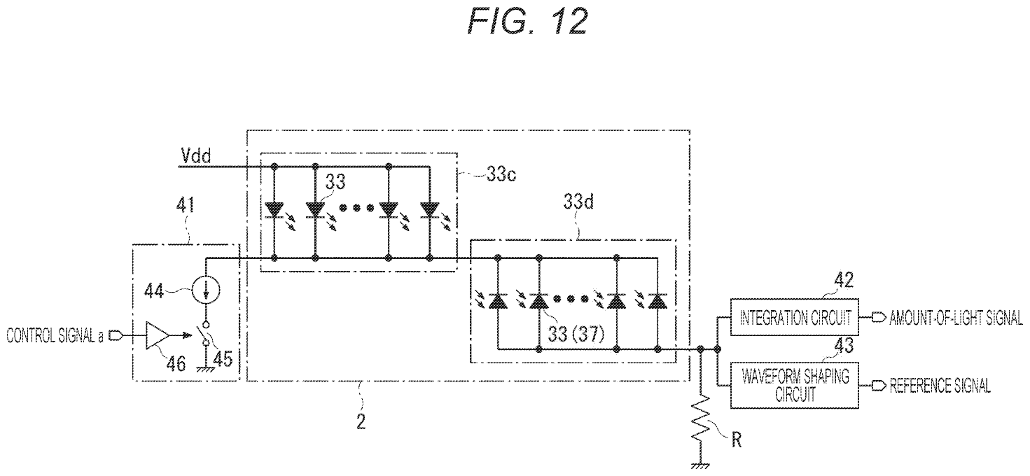

FIG. 11 is a modified example of FIG. 9 in which the integration circuit 42 and the waveform shaping circuit 43 (first waveform shaping circuit 51) are connected to an anode of the light emitting element 33 used as the light receiving element 37 among the plurality of light emitting elements 33. FIG. 12 is an equivalent circuit of FIG. 11, and illustrates an example in which the first light emitting element group 33c is used as the light emitting element 33 and the second light emitting element group 33d is used as the light receiving element 37.

In the case of the configurations of FIGS. 11 and 12, the amount-of-light signal and the reference signal can be generated on the basis of a light receiving signal in the light emitting element 33 used as the light receiving element 37. According to the configuration of FIG. 11, the light emitting element 33 that generates the amount-of-light signal and the reference signal and functions as the light receiving element 37 can be sequentially switched.

In this manner, in the second embodiment, the plurality of light emitting elements 33 in the surface emitting laser device 1 is classified into the plurality of light emitting element groups, and whether to use each light emitting element group as the light emitting element 33 or the light receiving element 37 is sequentially switched. Therefore, the number of the light emitting elements 33 that simultaneously emit light in the surface emitting laser device 1 can be reduced, and the number of consumed electrodes can be reduced. Furthermore, the light emitting elements 33 in the surface emitting laser device 1 can be used as the light emitting element 33 and the light receiving element 37 without bias, and thus, there is no possibility that the accuracy of distance measurement is lowered. In particular, the amount-of-light signal and the reference signal can be accurately detected by using each of the light emitting elements 33 in the surface emitting laser device 1 as the light receiving element 37 without bias.

### Third Embodiment

In a third embodiment, a laser safety measure is taken.

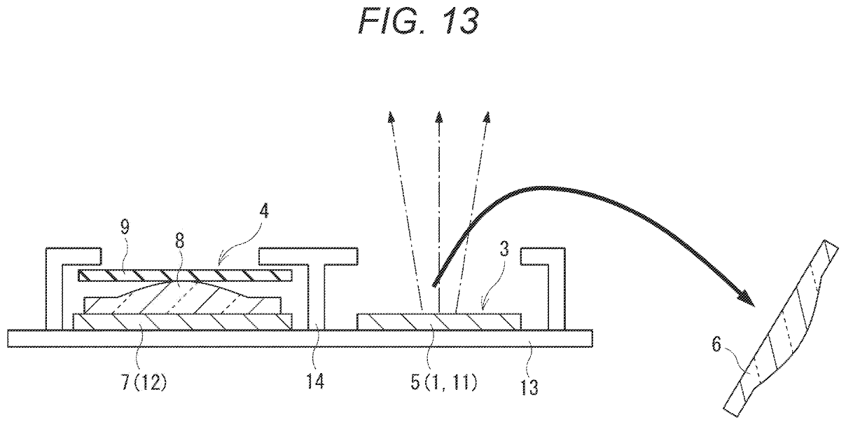

FIG. 13 is a diagram schematically depicting the distance measurement module 2 according to the third embodiment. When the output optical system 6 attached to the light emitting section 5 in the distance measurement module 2 falls off for some reason, laser light from the light emitting section 5 is emitted to the outside without passing through the output optical system 6, and there is a possibility that a light intensity of the laser light exceeds a laser safety standard. Furthermore, a diffuser configured to diffuse the laser light is sometimes provided in addition to the output optical system 6 although not illustrated in FIG. 13, and if the diffuser falls off, the laser light having the light intensity exceeding the laser safety standard is emitted.

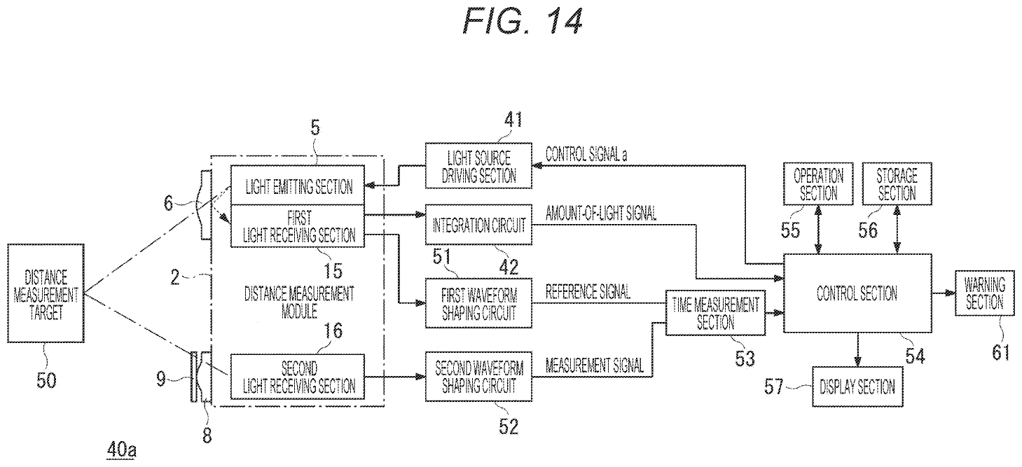

Therefore, the electronic apparatus 40 depicted in FIG. 14 detects fall-off of the output optical system 6 or the diffuser, and performs predetermined warning processing when fall-off is detected. The electronic apparatus 40 of FIG. 14 includes a warning section 61 in addition to the configuration of FIG. 7.

The control section 54 in FIG. 14 monitors an amount-of-light signal from the integration circuit 42. In a case where the amount-of-light signal is not output from the integration circuit 42 even in a case where a predetermined time elapses after the light emitting section 5 emits the laser light, or in a case where a signal level of the amount-of-light signal is lower than a predetermined signal level, the control section 54 determines that the output optical system 6 or the diffuser has fallen off, and transmits a predetermined signal to the warning section 61. When receiving the predetermined signal from the control section 54, the warning section 61 performs predetermined warning processing. For example, the display section 57 of the electronic apparatus 40 may display that there is a possibility of the fall-off of the output optical system 6 or the like, or may perform display to urge a repair request by forcibly stopping the light emission from the light emitting section 5.

In this manner, in the third embodiment, some light emitting elements 33 among the plurality of light emitting elements 33 in the surface emitting laser device 1 are used as the light receiving elements 37 not only to generate the amount-of-light signal and the reference signal for distance measurement but also to detect the fall-off of the output optical system 6 or the diffuser arranged in the vicinity of the light emitting section 5. Therefore, it is possible to detect the fall-off of the output optical system 6 or the diffuser arranged in the vicinity of the light emitting section 5 and perform the predetermined warning processing without separately providing the light receiving element 37.

### Fourth Embodiment

In a fourth embodiment, a safety measure is taken in a case where an intensity of laser light emitted from the light emitting section 5 greatly increases.

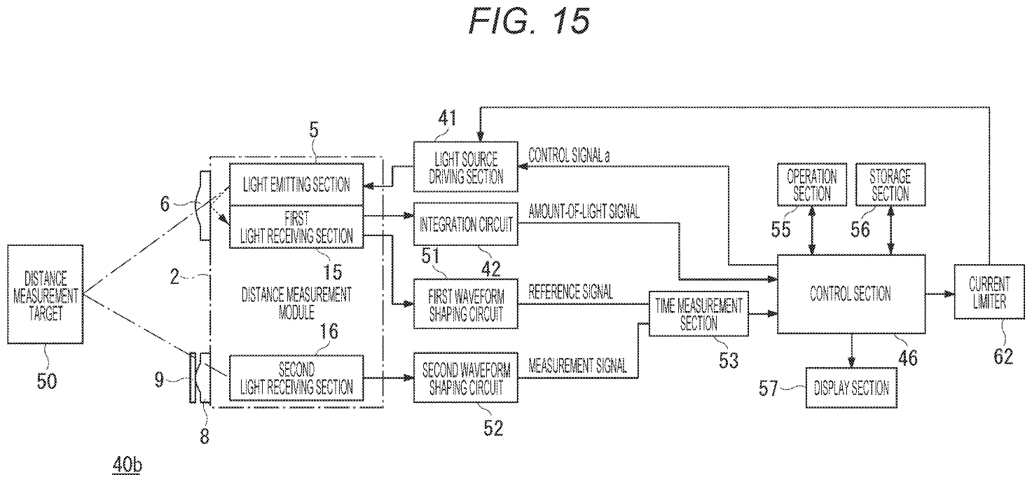

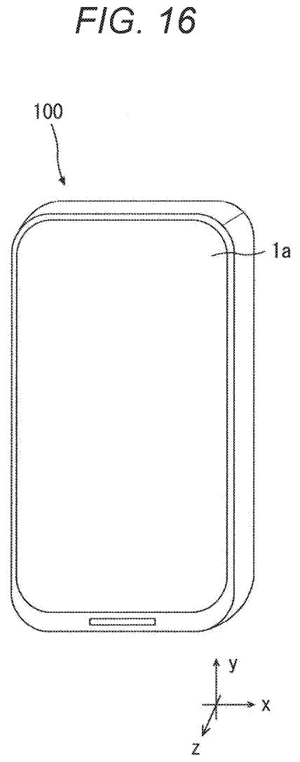

FIG. 15 is a block diagram depicting a schematic configuration of the electronic apparatus 40 according to a fourth embodiment. The electronic apparatus 40 of FIG. 15 includes a current limiter 62 in addition to the configuration of the electronic apparatus 40 of FIG. 7.

The current limiter 62 limits the current flowing through the current source 44 in the light source driving section 41 not to exceed a predetermined current amount on the basis of a control signal from the control section 54. When determining that a light intensity of laser light emitted from the light emitting section 5 exceeds a predetermined threshold on the basis of an amount-of-light signal from the integration circuit 42, the control section 54 transmits a control signal to the current limiter 62 so as to limit the current flowing through the light emitting element 33. The current limiter 62 limits the current flowing through the current source 44 in the light source driving section 41. Alternatively, the current flowing through the current source 44 may be set to zero to prevent the light emitting section 5 from emitting laser light.

In this manner, in the fourth embodiment, some of the light emitting elements 33 among the plurality of light emitting elements 33 in the surface emitting laser device 1, are used as the light receiving elements 37 to detect the amount-of-light signal, and the current flowing from the current source 44 that causes the current to flow through the light emitting element 33 is limited in a case where it is determined that the emitted light intensity of the laser light exceeds the predetermined threshold on the basis of the amount-of-light signal. Thus, when the emitted light intensity of the laser light becomes abnormally high for some reason, the emitted light intensity can be quickly reduced or the light emission itself can be stopped, and the safety measure for the laser light can be taken using the surface emitting laser device 1 without providing the separate light receiving element 37.

(Configuration Example of Electronic Apparatus)

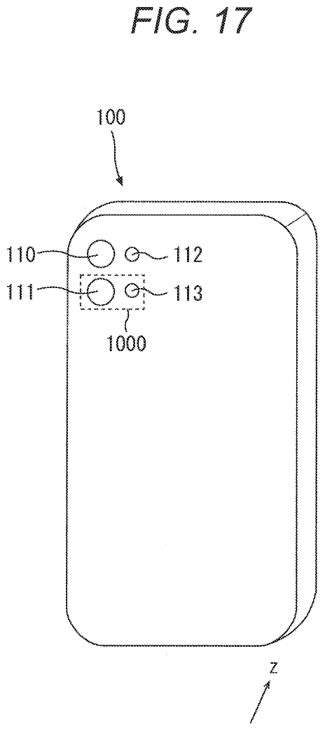

FIGS. 16 and 17 illustrate examples of an electronic apparatus 100 on which the distance measurement module 2 according to the present disclosure is mounted. FIG. 16 illustrates a configuration of the electronic apparatus 100 as viewed from a positive side in a z-axis direction. On the other hand, FIG. 17 illustrates a configuration of the electronic apparatus 100 as viewed from a negative side in the z-direction direction. The electronic apparatus 100 has, for example, a substantially flat plate shape, and includes a display section 1a on at least one surface (here, surface on the positive side in the z-axis direction). The display section 1a can display an image, for example, by liquid crystal, a micro LED, or an organic electroluminescence method. However, a display method in the display section 1a is not limited. Furthermore, the display section 1a may include a touch panel and a fingerprint sensor.

A first imaging section 110, a second imaging section 111, a first light emitting section 112, and a second light emitting section 113 are mounted on a surface of the electronic apparatus 100 on the negative side in the z-axis direction. The first imaging section 110 is, for example, a camera module capable of imaging a color image. The camera module includes, for example, a lens system and an imaging element that performs photoelectric conversion of light collected by the lens system. The first light emitting section 112 is, for example, a light source used as a flash of the first imaging section 110. As the first light emitting section 112, for example, a white LED can be used. However, a type of a light source used as the first light emitting section 112 is not limited.

The second imaging section 111 is, for example, an imaging element capable of distance measurement by a ToF method. The second imaging section 111 corresponds to, for example, the second light receiving section 16 in FIG. 7. The second light emitting section 113 can be used for the distance measurement by the ToF method and is a light source. The second light emitting section 113 corresponds to, for example, the light emitting section 5 in FIG. 7. In this manner, the electronic apparatus 100 depicted in FIGS. 16 and 17 includes the distance measurement module 2 in FIG. 7. The electronic apparatus 100 can execute various processes on the basis of a distance image output from the distance measurement module 2.

Here, the case where the electronic apparatus according to the present disclosure is the smartphone or a tablet has been described. However, the electronic apparatus according to the present disclosure may be, for example, other types of devices such as a game machine, a vehicle-mounted apparatus, a PC, and a monitoring camera.

The distance measurement module 2 according to the present disclosure may include a signal generator, a plurality of cascade-connected flip-flops, a circuit block, a pixel array, and a signal processing section. The signal generator is configured to generate a clock signal. The circuit block is configured to supply a first signal to a clock terminal of each of the plurality of flip-flops in response to the clock signal, and to supply a second signal to an input terminal of a first-stage flip-flop of the plurality of flip-flops. The pixel array includes pixels configured to be driven by pulse signals supplied from different stages of the plurality of flip-flops. The signal processing section is configured to generate the distance image on the basis of charge generated by photoelectric conversion in the pixels of the pixel array.

An electronic apparatus according to the present disclosure may include a signal generator, a plurality of cascade-connected flip-flops, a circuit block, and a pixel array. The signal generator is configured to generate a clock signal. The circuit block is configured to supply a first signal to a clock terminal of each of the plurality of flip-flops in response to the clock signal, and to supply a second signal to an input terminal of a first-stage flip-flop of the plurality of flip-flops. The pixel array includes pixels configured to be driven by pulse signals supplied from different stages of the plurality of flip-flops.

(Example of Application to Mobile Body)

The technology according to the present disclosure (present technology) can be applied to various products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a ship, and a robot.

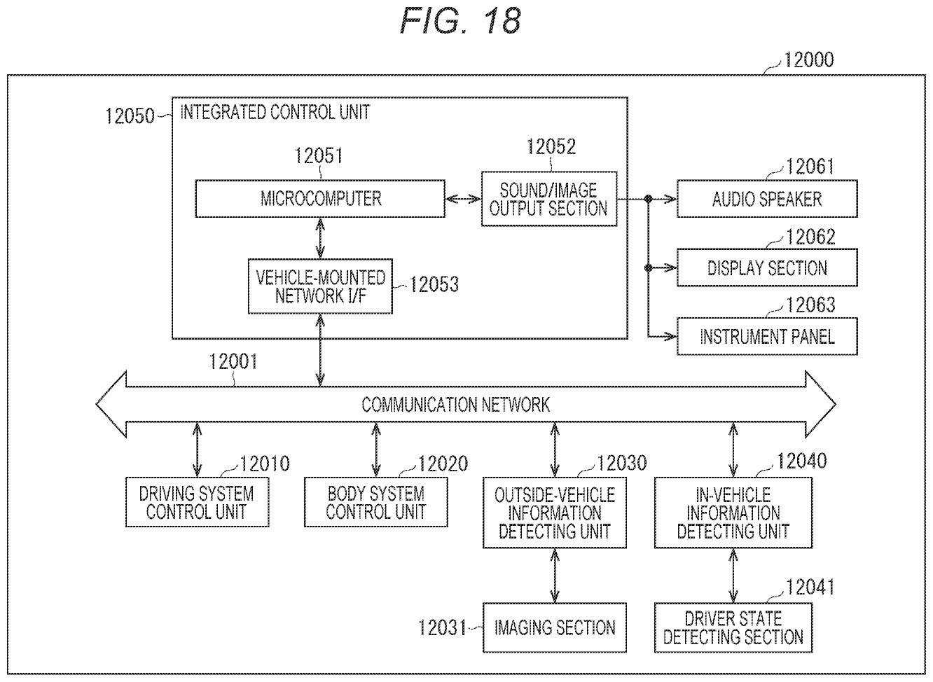

FIG. 18 is a block diagram depicting an example of a schematic configuration of a vehicle control system as an example of a mobile body control system to which the technology according to the present disclosure can be applied.

The vehicle control system 12000 includes a plurality of electronic control units connected to each other via a communication network 12001. In the example depicted in FIG. 18, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 18, an audio speaker 12061, a display section 12062, and an instrument panel 12063 are illustrated as the output device. The display section 12062 may, for example, include at least one of an on-board display and a head-up display.

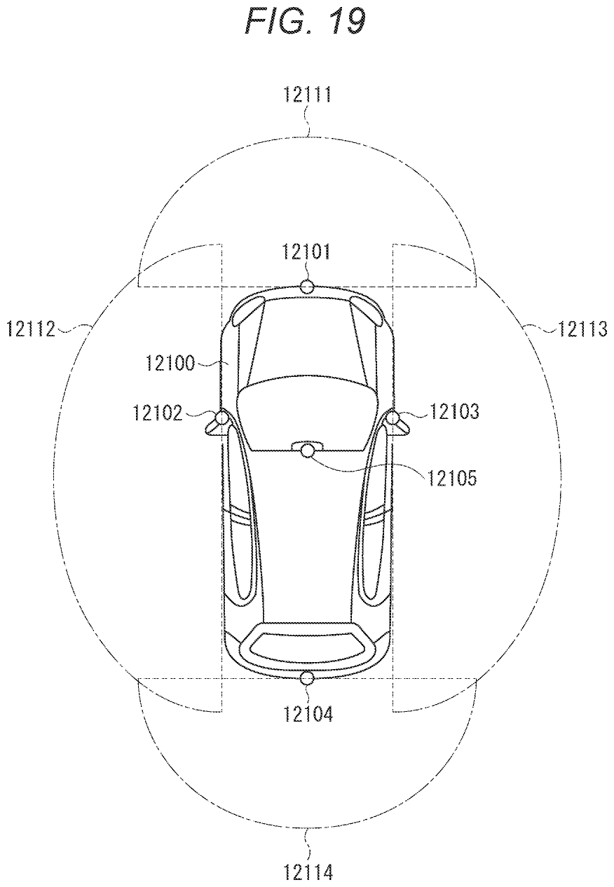

FIG. 19 is a diagram depicting an example of the installation position of the imaging section 12031.

In FIG. 19, the vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The image of the front acquired by the imaging sections 12101 and 12105 is mainly used to detect a preceding vehicle, a pedestrian, an obstacle, a traffic light, a traffic sign, a lane, and the like.

Note that FIG. 19 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described as above. The technology according to the present disclosure can be applied to, for example, the imaging section 12031 among the above-described configurations. Specifically, an imaging element according to the present disclosure can be mounted on the imaging section 12031. When the technology according to the present disclosure is applied to the imaging section 12031, it is possible to improve the resolution of a distance image while suppressing the generation of electromagnetic noise, and it is possible to enhance the functionality and safety of the vehicle 12100.

Note that the present technology can have the following configurations.

(1) A surface emitting laser device including a surface emitting section having a plurality of light emitting elements arranged on a substrate,

in which some of the plurality of light emitting elements are used as light receiving elements.

(2) The surface emitting laser device according to (1), further including an optical system that outputs the light emitted from the surface emitting section,

in which the plurality of light emitting elements includes:

a first element that emits light; and

a second element that receives light which is the light emitted from the first element and reflected by the optical system.

(3) The surface emitting laser device according to (2), in which a forward bias voltage is supplied to the first element, and a reverse bias voltage is supplied to the second element.

(4) The surface emitting laser device according to (3), in which a cathode of the first element and a cathode of the second element are connected in common, a power supply voltage is supplied to an anode of the first element, and a signal corresponding to a received light amount is output from an anode of the second element.

(5) The surface emitting laser device according to (4), further including a light source driving section that is connected to the cathode of the first element and the cathode of the second element and switches whether or not to cause a current corresponding to an emitted light intensity to flow to the first element.

(6) The surface emitting laser device according to (5), in which the light source driving section variably controls a current flowing through the first element when the first element is caused to emit light on the basis of an amount-of-light signal indicating a light intensity of the light received by the second element.

(7) The surface emitting laser device according to any one of (2) to (6), further including a voltage conversion circuit that is connected between the anode of the second element and a reference voltage node and generates a voltage signal corresponding to an intensity of the light received by the second element.

(8) The surface emitting laser device according to any one of (1) to (7), in which the plurality of light emitting elements is arranged in a first direction and a second direction intersecting each other on the substrate, and

four light emitting elements at four corners out of the plurality of light emitting elements are used as the light receiving elements.

(9) The surface emitting laser device according to any one of (1) to (7), in which the plurality of light emitting elements is classified into a plurality of light emitting element groups each including two or more of the light emitting elements,

each of the plurality of light emitting element groups is sequentially caused to emit light in a time-shifted manner, and

the light emitting elements included in the light emitting element group that does not emit light are used as the light receiving elements.

(10) The surface emitting laser device according to (9), in which the plurality of light emitting element groups is formed by arranging the light emitting element groups each including two or more light emitting elements arranged in a first direction to form a plurality of columns in a second direction intersecting the first direction,

each of the light emitting element groups in the plurality of columns is sequentially caused to emit light column by column in a time-shifted manner, and

the light emitting elements included in the light emitting element group of a column that does not emit light are used as the light receiving elements.

(11) The surface emitting laser device according to any one of (1) to (7), in which some light emitting elements out of the plurality of light emitting elements are test light emitting elements,

the test light emitting elements are arranged at a different place on the substrate from light emitting elements other than the some light emitting elements, and

the test light emitting elements are used as the light receiving elements.

(12) An electronic apparatus including: a surface emitting section having a plurality of light emitting elements arranged on a substrate;

an optical system configured to output light emitted from the surface emitting section; and

a control section that controls light intensities of the plurality of light emitting elements,

in which the plurality of light emitting elements includes a first element that emits light, and a second element that receives light, which is the light emitted from the first element and reflected by the optical system, and

the control section controls a light intensity of the first element on the basis of an intensity of the light received by the second element.

(13) The electronic apparatus according to (12), further including an amount-of-light signal generation circuit that generates an amount-of-light signal indicating the intensity of the light received by the second element,

in which the control section controls light intensity of the first element on the basis of the amount-of-light signal.

(14) The electronic apparatus according to (13), further including a current source that variably controls a current flowing through the first element when the first element is caused to emit light,

in which the control section adjusts the current of the current source on the basis of the amount-of-light signal.

(15) The electronic apparatus according to (13), further including a light source driving section that controls whether or not to cause the first element to emit light,

in which the control section stops the light emission of the first element in a case where the amount-of-light signal exceeds a predetermined reference amount.

(16) The electronic apparatus according to any one of (12) to (15), further including a reference signal generation circuit that generates a reference signal indicating a timing at which light is received by the second element.

(17) The electronic apparatus according to (16), further including: a light receiving element that receives reflected light which is the light emitted from the first element and is reflected by an object; and

a time measuring section that detects a time difference between a time at which the light receiving element receives the reflected light and a time at which the first element emits light on the basis of a light receiving signal output from the light receiving element and the reference signal.

(18) The electronic apparatus according to any one of (12) to (17), further including: a determination section that determines whether or not the second element has received light until a lapse of a predetermined time after the first element receives light; and

a warning section that performs predetermined warning processing when the determination section determines that the second element has not received light until the lapse of the predetermined time.

(19) The electronic apparatus according to any one of (12) to (18), further including: a first semiconductor device including the surface emitting section; and

a second semiconductor device including the control section,

in which the optical system is arranged on a light output surface side of the first semiconductor device.

Aspects of the present disclosure are not limited to the above-described respective embodiments, but include various modifications that can be conceived by those skilled in the art, and effects of the present disclosure are not limited to the above-described contents. That is, various additions, changes, and partial deletions can be made within a scope not departing from a conceptual idea and a spirit of the present disclosure derived from the contents defined in the claims and equivalents thereof.

### REFERENCE SIGNS LIST

1 Surface emitting laser device
2 Distance measurement module
3 Light emitting device
4 Light receiving device
5 Light emitting section
6 Output optical system
7 Light receiving section
8 Input optical system
9 Band-pass filter
11 Semiconductor chip
12 Semiconductor chip
13 Support substrate
14 Light shielding member
21 Support substrate
22 Heat dissipation substrate
23 LDD substrate
24 LD chip
25 Bonding member
26 Lens holding section
31 Substrate
32 Laminated film
33 Light emitting element
34 Anode electrode
35 Cathode electrode
36 Pad
37 Light receiving element
40 Electronic apparatus
41 Light source driving section
42 Integration circuit
43 Waveform shaping circuit
44 Current source
45 Selector
46 Buffer
51 First waveform shaping circuit
52 Second waveform shaping circuit
53 Time measurement section
54 Control section
55 Operation section
56 Storage section
57 Display section

1. A surface emitting laser device comprising
a surface emitting section having a plurality of light emitting elements arranged on a substrate,
wherein some of the plurality of light emitting elements are used as light receiving elements.

2. The surface emitting laser device according to claim 1, further comprising
an optical system that outputs the light emitted from the surface emitting section,
wherein the plurality of light emitting elements includes:
a first element that emits light; and
a second element that receives light which is the light emitted from the first element and reflected by the optical system.

3. The surface emitting laser device according to claim 2, wherein
a forward bias voltage is supplied to the first element, and a reverse bias voltage is supplied to the second element.

4. The surface emitting laser device according to claim 3, wherein
a cathode of the first element and a cathode of the second element are connected in common, a power supply voltage is supplied to an anode of the first element, and a signal corresponding to a received light amount is output from an anode of the second element.

5. The surface emitting laser device according to claim 4, further comprising
a light source driving section that is connected to the cathode of the first element and the cathode of the second element and switches whether or not to cause a current corresponding to an emitted light intensity to flow to the first element.

6. The surface emitting laser device according to claim 5, wherein
the light source driving section variably controls a current flowing through the first element when the first element is caused to emit light on a basis of an amount-of-light signal indicating a light intensity of the light received by the second element.

7. The surface emitting laser device according to claim 2, further comprising
a voltage conversion circuit that is connected between the anode of the second element and a reference voltage node and generates a voltage signal corresponding to an intensity of the light received by the second element.

8. The surface emitting laser device according to claim 1, wherein
the plurality of light emitting elements is arranged in a first direction and a second direction intersecting each other on the substrate, and
four light emitting elements at four corners out of the plurality of light emitting elements are used as the light receiving elements.

9. The surface emitting laser device according to claim 1, wherein
the plurality of light emitting elements is classified into a plurality of light emitting element groups each including two or more of the light emitting elements,
each of the plurality of light emitting element groups is sequentially caused to emit light in a time-shifted manner, and
the light emitting elements included in the light emitting element group that does not emit light are used as the light receiving elements.

10. The surface emitting laser device according to claim 9, wherein
the plurality of light emitting element groups is formed by arranging the light emitting element groups each including two or more light emitting elements arranged in a first direction to form a plurality of columns in a second direction intersecting the first direction,
each of the light emitting element groups in the plurality of columns is sequentially caused to emit light column by column in a time-shifted manner, and
the light emitting elements included in the light emitting element group of a column that does not emit light are used as the light receiving elements.

11. The surface emitting laser device according to claim 1, wherein
some light emitting elements out of the plurality of light emitting elements are test light emitting elements,
the test light emitting elements are arranged at a different place on the substrate from light emitting elements other than the some light emitting elements, and
the test light emitting elements are used as the light receiving elements.

12. An electronic apparatus comprising:
a surface emitting section having a plurality of light emitting elements arranged on a substrate;
an optical system configured to output light emitted from the surface emitting section; and
a control section that controls light intensities of the plurality of light emitting elements,
wherein the plurality of light emitting elements includes a first element that emits light, and a second element that receives light, which is the light emitted from the first element and reflected by the optical system, and
the control section controls a light intensity of the first element on a basis of an intensity of the light received by the second element.

13. The electronic apparatus according to claim 12, further comprising
an amount-of-light signal generation circuit that generates an amount-of-light signal indicating the intensity of the light received by the second element,
wherein the control section controls light intensity of the first element on a basis of the amount-of-light signal.

14. The electronic apparatus according to claim 13, further comprising
a current source that variably controls a current flowing through the first element when the first element is caused to emit light,
wherein the control section adjusts the current of the current source on a basis of the amount-of-light signal.

15. The electronic apparatus according to claim 13, further comprising
a light source driving section that controls whether or not to cause the first element to emit light,
wherein the control section stops the light emission of the first element in a case where the amount-of-light signal exceeds a predetermined reference amount.

16. The electronic apparatus according to claim 12, further comprising
a reference signal generation circuit that generates a reference signal indicating a timing at which light is received by the second element.

17. The electronic apparatus according to claim 16, further comprising:
a light receiving element that receives reflected light which is the light emitted from the first element and is reflected by an object; and
a time measuring section that detects a time difference between a time at which the light receiving element receives the reflected light and a time at which the first element emits light on a basis of a light receiving signal output from the light receiving element and the reference signal.

18. The electronic apparatus according to claim 12, further comprising:
a determination section that determines whether or not the second element has received light until a lapse of a predetermined time after the first element receives light; and
a warning section that performs predetermined warning processing when the determination section determines that the second element has not received light until the lapse of the predetermined time.

19. The electronic apparatus according to claim 12, further comprising:
a first semiconductor device including the surface emitting section; and
a second semiconductor device including the control section,
wherein the optical system is arranged on a light output surface side of the first semiconductor device.
